(19) United States
(12) Patent Application Publication
(10) Pub. No.: US 2007/0254493 A1
(43) Pub. Date: Nov. 1, 2007

(54) Integrated thermal unit having vertically arranged bake and chill plates

(75) Inventors: Martin Jeff Salinas, San Jose, CA (US); Natarajan Ramanan, San Jose, CA (US); Leon Volfovski, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/413,960

(22) Filed: Apr. 28, 2006

(51) Int. Cl. G03B 27/52; H01L 21/00

(52) U.S. Cl. 438/795; 355/55

(57) ABSTRACT

An integrated thermal unit comprising a housing; a bake station positioned within the housing, the bake station comprising a bake plate configured to heat a substrate supported on a surface of the bake plate; a chill station positioned within the housing, the chill station comprising a chill plate configured to cool a substrate supported on a surface of the chill plate; and a substrate receiving station positioned within the housing, the substrate receiving station configured to hold a substrate; wherein the bake station, chill station and substrate receiving station are arranged in a vertical stack within the housing. In some embodiments the integrated thermal unit further comprises a substrate transfer shuttle positioned within the housing and adapted to transfer substrates between the substrate receiving station, bake station and chill stations.

### BACKGROUND OF THE INVENTION

The present invention relates generally to the field of substrate processing equipment. More particularly, the present invention relates to a method and apparatus for controlling the temperature of substrates, such as semiconductor substrates, used in the formation of integrated circuits.

Modern integrated circuits contain millions of individual elements that are formed by patterning the materials, such as silicon, metal and/or dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre-and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that every substrate processed within the track lithography tool for a particular application has the same “wafer history.” A substrate's wafer history is generally monitored and controlled by process engineers to ensure that all of the device fabrication processing variables that may later affect a device's performance are controlled, so that all substrates in the same batch are always processed the same way.

To ensure that each substrate has the same “wafer history” requires that each substrate experiences the same repeatable substrate processing steps (e.g., consistent coating process, consistent hard bake process, consistent chill process, etc.) and the timing between the various processing steps is the same for each substrate. Lithography type device fabrication processes can be especially sensitive to variations in process recipe variables and the timing between the recipe steps, which directly affects process variability and ultimately device performance.

In view of these requirements, the semiconductor industry is continuously researching methods and developing tools and techniques that can improve the uniformity in wafer history for track lithography and other types of cluster tools.

### BRIEF SUMMARY OF THE INVENTION

According to the present invention, methods and apparatus related to semiconductor manufacturing equipment are provided. More particularly, embodiments of the present invention relate to a method and apparatus for heating and/or cooling a substrate in a highly controllable manner. Embodiments of the invention contemplate multiple substrates being processed according to the same heating and cooling sequence in a highly controllable manner thus helping to ensure a consistent wafer history for each substrate. While some embodiments of the invention are particularly useful in heating and/or cooling substrates in a chamber or station of a track lithography tool, other embodiments of the invention can be used in other applications where it is desirable to heat and cool substrates in a highly controllable manner.

According to one embodiment of the invention, an integrated thermal unit is disclosed. The integrated thermal unit comprises a housing, a bake station positioned within the housing, a chill station positioned within the housing, and a substrate receiving station positioned within the housing where the bake station, chill station and substrate receiving station are all arranged in a vertical stack. The bake station includes a bake plate configured to heat a substrate supported on a surface of the bake plate, the chill station includes a chill plate configured to cool a substrate supported on a surface of the chill plate and the substrate receiving station is adapted to hold a substrate. The integrated thermal unit may further include a substrate transfer shuttle positioned within the housing and configured to transfer substrates from the bake plate to the chill plate within the integrated thermal unit.

In some embodiments the substrate transfer shuttle has a temperature controlled surface that is capable of cooling a substrate heated by the bake plate. Also, in some embodiments, the bake plate is arranged in the vertical stack within the integrated thermal unit above the chill plate while in other embodiments the chill plate is arranged above the bake plate.

Certain other embodiments of the invention pertain to a track lithography tool comprising a plurality of pod assemblies adapted to accept one or more cassettes of wafers and one or more robots adapted to transfer wafers from the one or more pod assemblies to processing modules within the track lithography tool, wherein at least one of the processing modules includes an integrated thermal unit according to one of the embodiments described above.

Still other embodiments of the invention pertain to methods of processing a substrate in an integrated thermal unit. According to one such embodiment, a method of processing a substrate in a integrated thermal unit having a bake station, a chill station and a substrate receiving station all arranged in a vertical stack within the integrated thermal unit comprises transferring a substrate having a liquid resist material applied thereon into the integrated thermal unit and onto the substrate receiving station; transferring the substrate from the substrate receiving station to the bake station with a substrate transfer device; heating the substrate on a bake plate within the bake station; transferring the substrate from the bake station to the chill station with the substrate transfer device; cooling the substrate with a chill plate within the chill station; and transferring the substrate from the chill station out of the integrated thermal unit. In some embodiments a second substrate can be transferred into the integrated thermal unit and positioned on the substrate support surface at the substrate receiving station while the first substrate is being heated by the bake plate.

Many benefits are achieved by way of the present invention over conventional techniques. For example, including bake and chill plates in one integrated unit minimizes the delay associated with transferring a baked wafer to the chill plate. Also, the inclusion of a shuttle having a temperature controlled substrate holding surface that transfers wafers between the bake and chill plates provides an additional degree of control over each wafer's thermal history thus enabling a more uniform thermal history among multiple wafers. Moreover, embodiments of the invention increase chamber throughput by decreasing the load on the main, central robot(s) of a track lithography tool and provide a safe haven for post-bake wafers in case of a malfunction of a main, central robot. Other embodiments increase wafer throughput by decreasing the amount of time it takes to change the set point temperature of a bake plate from a first temperature to a second temperature lower than the first temperature. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified cross-sectional view of one embodiment of an integrated thermal unit according to the present invention;

FIG. 2 is a simplified top plan view of the integrated thermal unit depicted in FIG. 1;

FIG. 3 is a simplified perspective view of the integrated thermal unit depicted in FIGS. 1 and 2;

FIG. 4 is perspective view of bake station 12 shown FIG. 1 according to one embodiment of the invention;

FIG. 5 is a perspective view of a cross-section of bake station 12 shown FIG. 4;

FIG. 6 is a cross-sectional view of bake station 12 shown in FIG. 4;

FIG. 7 is bottom perspective view of bake station 12 shown FIG. 4;

FIG. 8 is a perspective view of chill plate 30 shown FIG. 1 according to one embodiment of the invention;

FIG. 9 is a perspective view of chill shuttle 18 shown FIG. 1 according to one embodiment of the invention;

FIG. 10 is a block diagram that illustrates a sequence of events that are performed according to one embodiment of the method of the present invention;

FIG. 11 is a plan view of one embodiment of a track lithography tool 200 according to one embodiment of the present invention;

FIG. 12 is a flowchart illustrating an exemplary processing sequence for a semiconductor substrate processed by track lithography tool 200 shown in FIG. 11.

### DETAILED DESCRIPTION OF THE INVENTION

The present invention generally provides a method and apparatus for heating and cooling substrates in a highly controllable manner. While it is to be recognized that embodiments of the invention are particularly useful in helping to ensure a consistent wafer history for each substrate in a plurality of substrates that are heated and cooled according a particular thermal recipe within a track lithography tool, other embodiments of the invention can be used in other applications where it is desirable to heat and cool substrates in a highly controllable manner. Note the terms “substrate” and “wafer” are sometimes used herein interchangeably and are sometimes specifically used in reference to a semiconductor wafer upon which integrated circuits are formed. A person of skill in the art will recognize the present invention is not limited to processing semiconductor wafers and can be used to process any substrate for which a highly controlled thermal treatment is desirable.

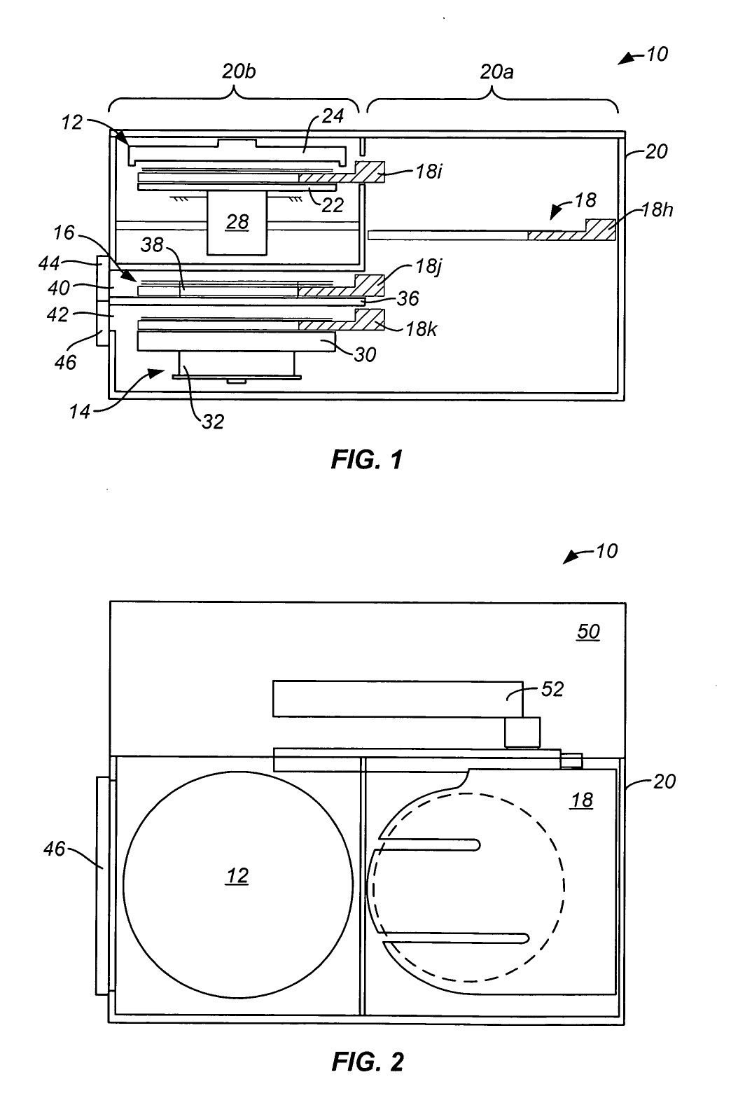

Referring to FIGS. 1 and 2, which are simplified cross-sectional and top plan views, respectfully, of one embodiment of an integrated thermal unit 10 according to the present invention. Integrated thermal unit 10 includes a bake station 12, a chill station 14, a substrate receiving station 16 and a shuttle 18 all within an enclosed housing 20. Bake station 12, chill station 14 and substrate receiving station 16 are all arranged in a vertical stack within portion 206 of housing 20. Shuttle 18 can be moved along both the x-and z-axis for transferring substrates between substrate receiving station 16, bake station 12 and chill station 14 as needed. Bake station 12 includes a bake plate 22, an enclosure 24 and a chill base (not shown in FIGS. 1 or 2). Bake plate 22 is moveable between a wafer loading position (shown in FIG. 1), a closed heating position in which the bake plate is urged towards and within clam shell enclosure 24 by a motorized lift 28 and a cooling position in which the bake plate contacts the chill base. The chill base is engageably coupled to bake plate chill to enable the set point temperature of the bake plate to be rapidly changed from a relatively high, bake temperature to a lower bake temperature when, for example, switching to a new thermal recipe.

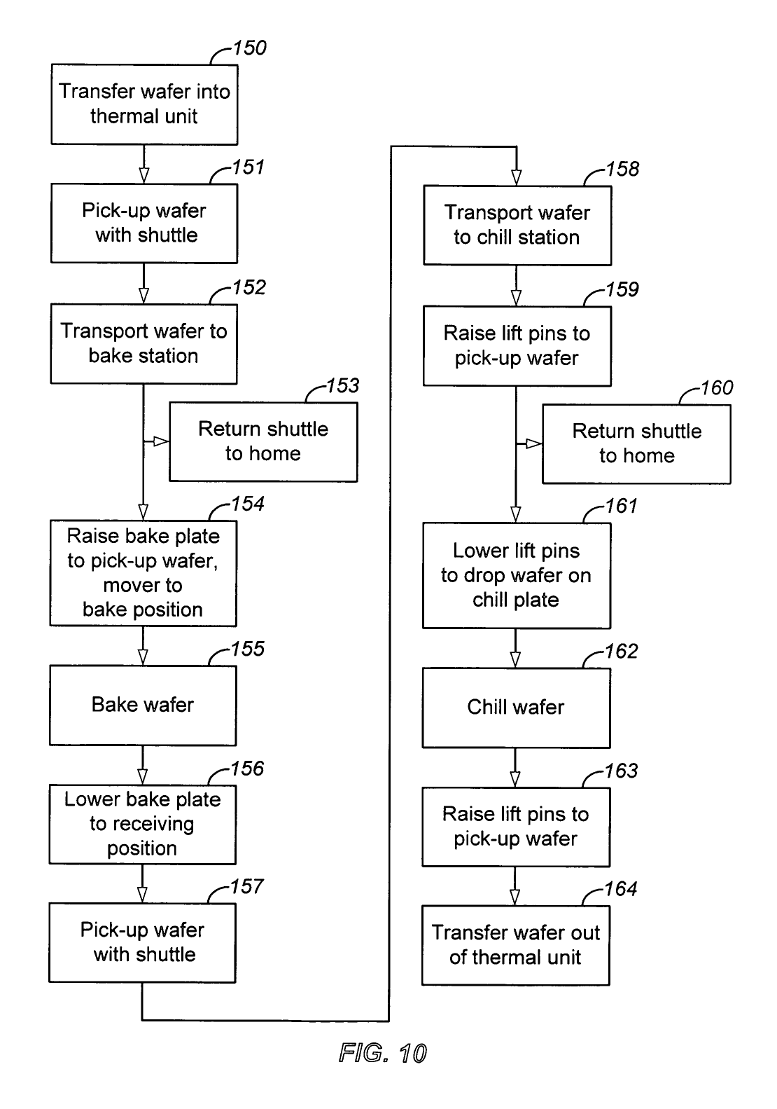

Chill station 14 includes a chill plate 30 that accurately and quickly cools a substrate after being treated at bake station 12 and lift pins 32 that are extendable through the surface of chill plate 30. Substrate receiving station 16 receives a substrate introduced into thermal unit 10 upon a substrate receiving surface, which in the embodiment shown in FIGS. 1 and 2 is the top of stationary lift pins 38. Lift pins 32 are operatively coupled to raise a substrate off of chill plate 30 so that the substrate can be picked up by shuttle 18 and transferred to a next station as described in conjunction with FIG. 10. A particle shield 36 separates chill station 14 and substrate receiving station 16 and protects a wafer being processed at the chill station from particles that may be associated with movement of shuttle 18 into station 16 over the chill plate.

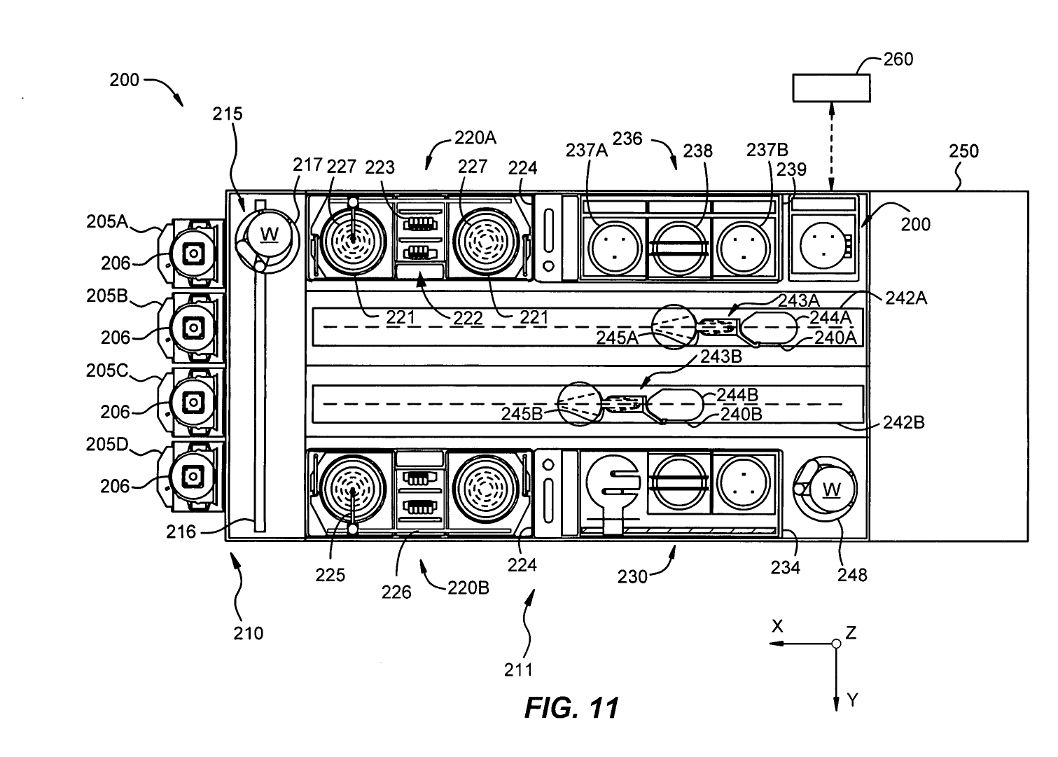

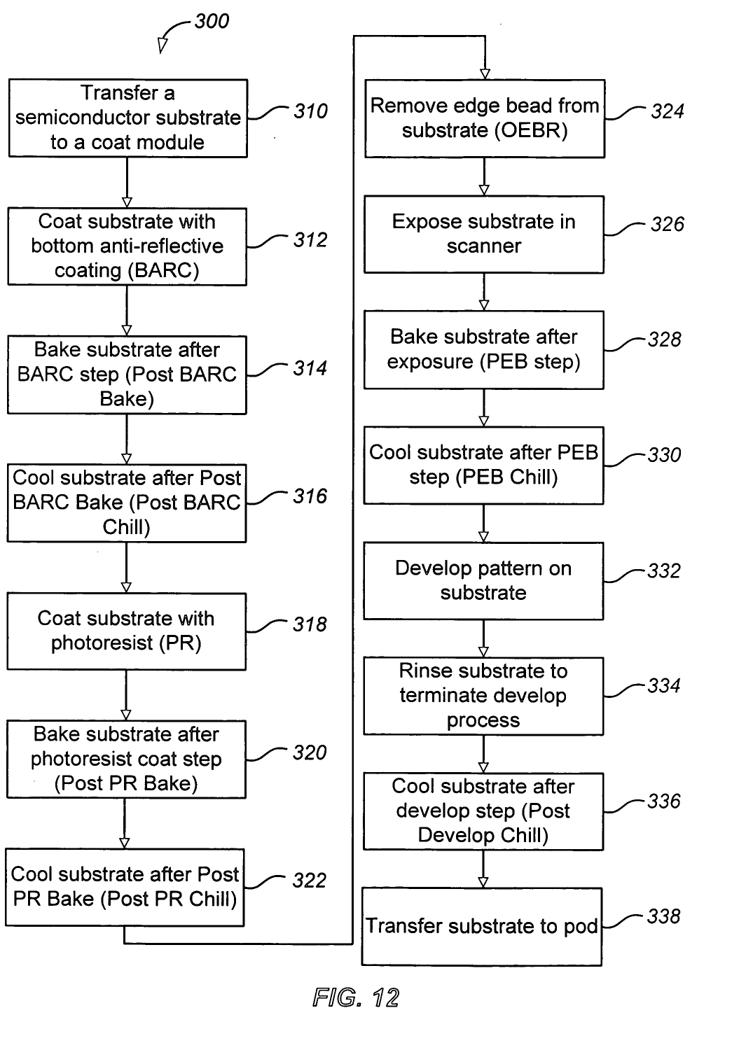

As shown in FIGS. 1 and 2, integrated thermal unit 10 includes an exterior housing 20 made of aluminum or another suitable material. Housing 20 is generally rectangular in shape and sized to allow bake station 12, chill station 14 and substrate receiving station 16 to be stacked vertically one on top of the other and allow multiple integrated thermal units to be stacked on top of each other in a track lithography tool as described below with respect to FIGS. 11 and 12. In one particular embodiment, housing 20 is slightly less than 40 centimeters high.

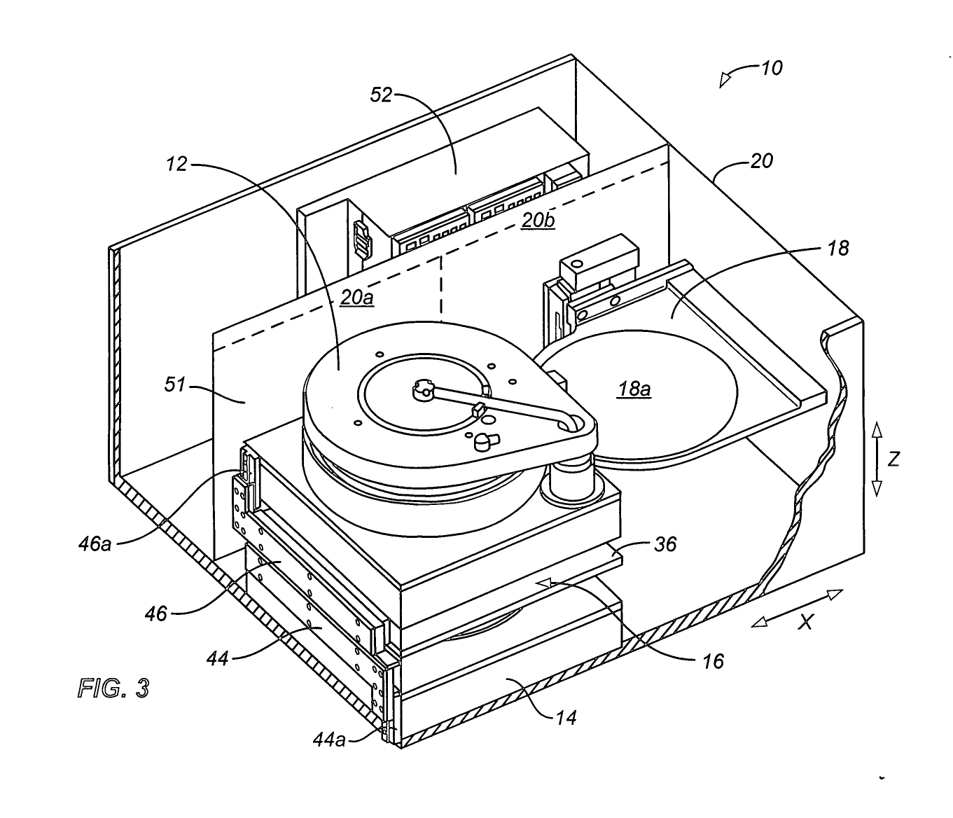

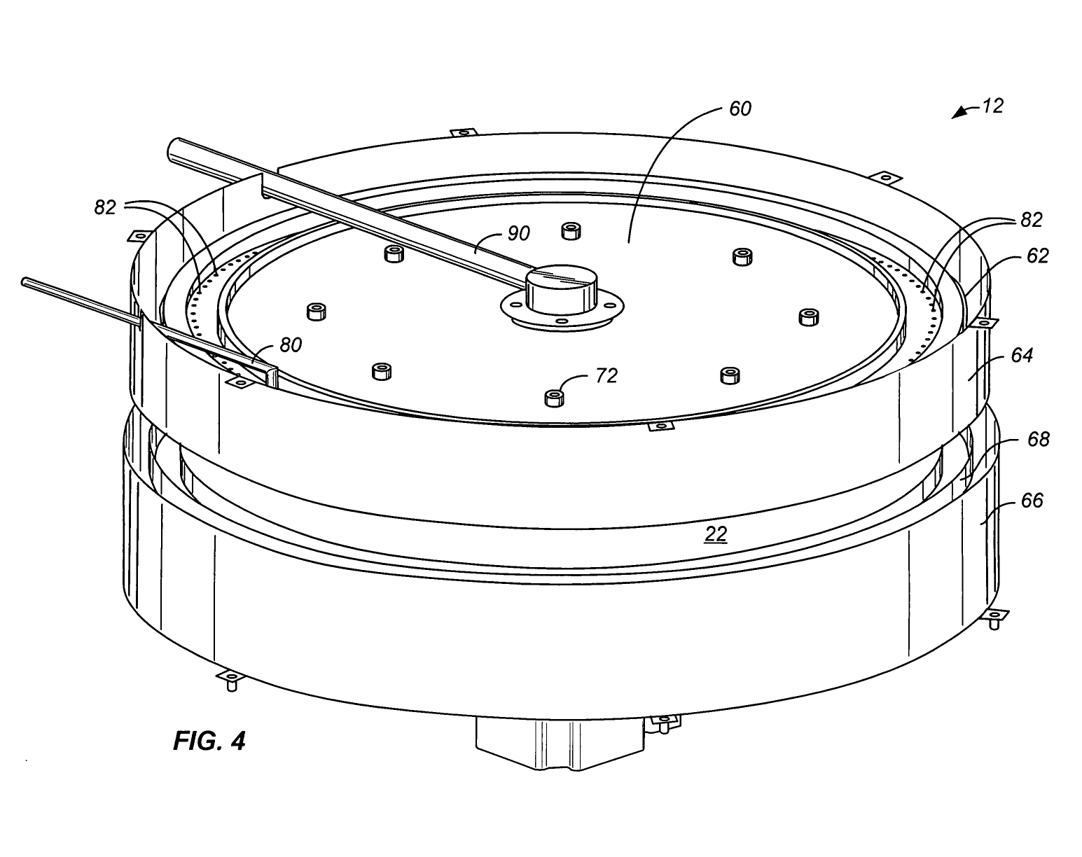

Housing 20 includes two elongated openings 40, 42 that allow substrates to be transferred into and out of the thermal unit. Chill station 14 and substrate receiving station 16 are each positioned horizontally adjacent to elongated openings 40 and 42. Opening 40 is operatively coupled to be closed and sealed by shutter 44 (shown in FIG. 3) which slides along a track 44a and opening 42 is operatively coupled to be closed and sealed by shutter 46 (also shown in FIG. 3) which slides along a track 46a. Shutters 44 and 46 shield the integrated thermal unit from the outer environment, such as the interior robot transfer area of a track lithography tool. Housing 20 may include coolant channels (not shown) that allow a coolant fluid to be circulated through the channels in order to control the temperature of the housing and minimize temperature variations within integrated thermal unit 10.

Also shown in FIG. 2 in an encasing 52 which houses a shuttle motor along with various control circuitry which controls the precision baking operation of bake station 12 and the precision cooling operation of chill station 14. The control circuitry also controls the operation of the shuttle motor to move linearly along the length of the thermal unit and vertically within the thermal unit as discussed in more detail below. In one embodiment, the control circuitry is positioned near stations 12 and 14 (e.g., within three feet) in order to enable more accurate and responsive control of temperature adjusting mechanisms associated with each station. An interior dividing wall 51 separates encasing 52 and the motor and control circuitry therein from the areas 20a, 20b of thermal unit 10 through which substrates pass.

FIG. 3 is a simplified perspective view of integrated thermal unit 10 depicted in FIGS. 1 and 2. In FIG. 3, bake station 12, chill station 14, substrate receiving station 16 and shuttle 18 are all visible. While positioned within area 20a of thermal unit 10, shuttle 18 can be moved linearly along the z-axis by the motor within encasing 52 to reach different levels of the bake, chill and substrate receiving stations. Once the shuttle reaches an appropriate vertical height, the motor can move shuttle 18 linearly along the x-axis to position the shuttle appropriately to lift or drop-off a substrate at the appropriate station. In some instances, for example at chill station 14, a substrate can be lifted off or dropped onto shuttle 18 by raising or lowering appropriate lift pins. In other instances where the lift pins are stationary, the substrate can be lifted off or dropped onto the shuttle by slightly raising or lowering the shuttle along the z-axis while the shuttle is appropriately positioned within portion 20b of unit 10. It should be noted that FIG. 1 shows shuttle 18 in four different positions including a first position 18h within region 20a of the integrated thermal unit in which the shuttle can be moved vertically as discussed above, a second position 18i in which shuttle 18 has been moved into bake station 12, a third position 18j in which shuttle 18 has been moved into substrate receiving station 16 and a fourth position 18k in which shuttle 18 has been moved into chill station 14.

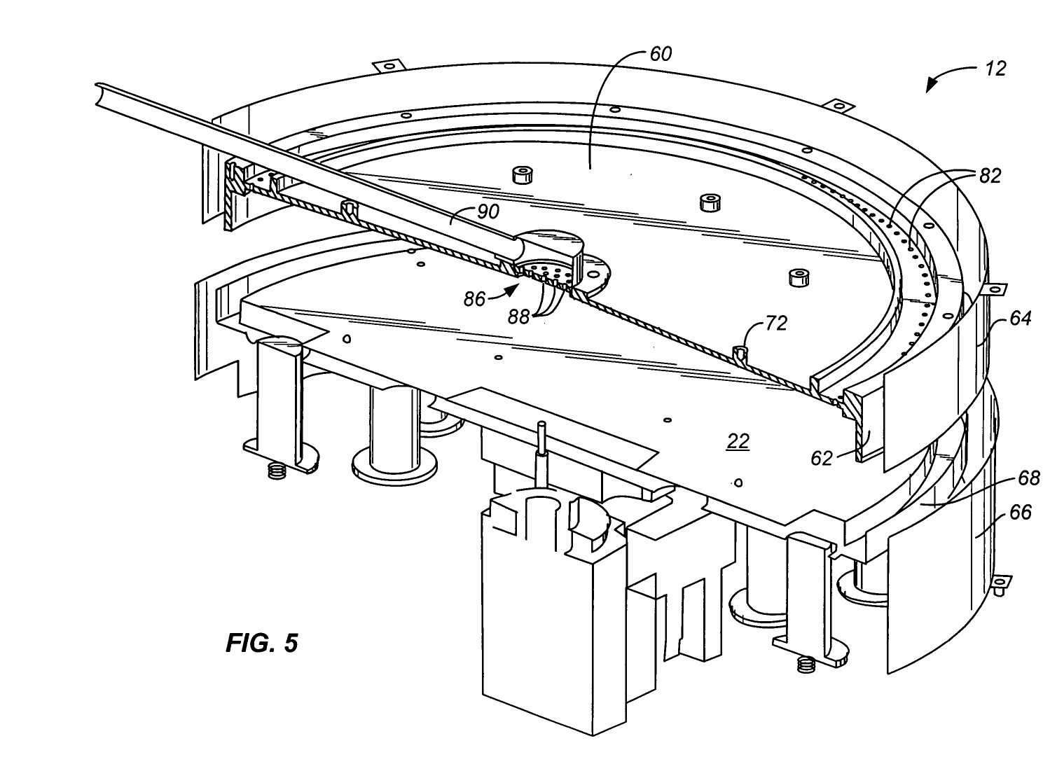

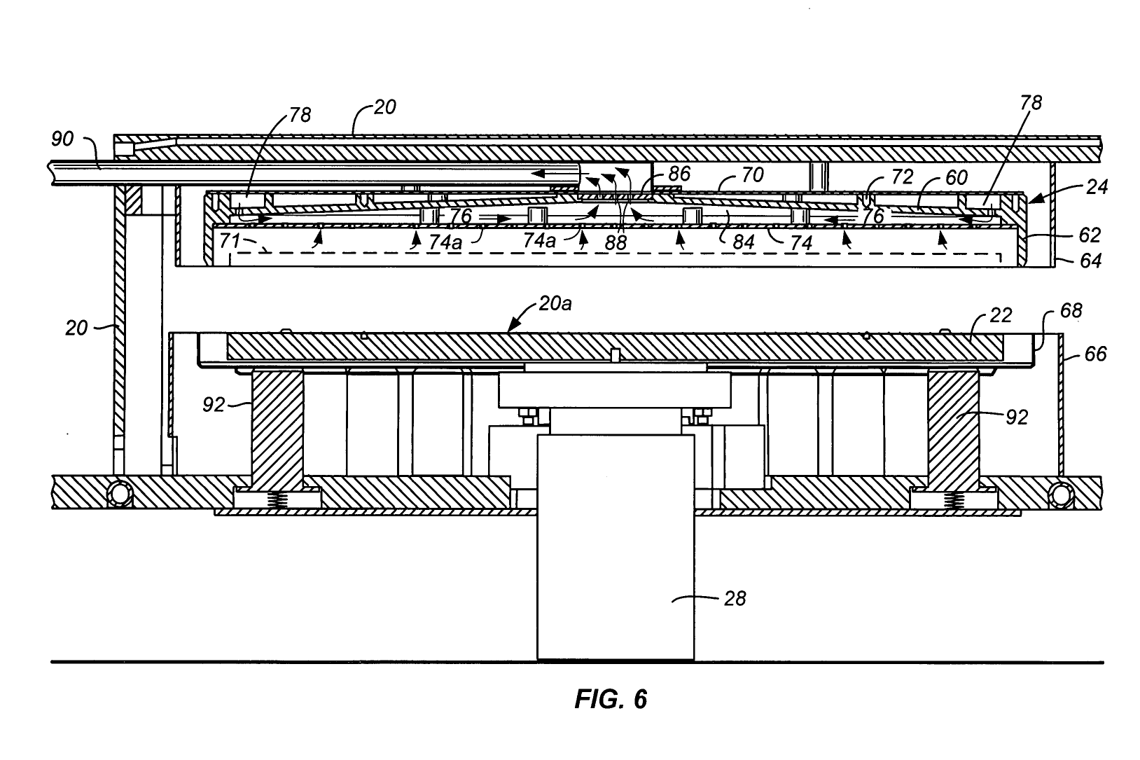

Reference is now made to FIGS. 4, 5 and 6 where FIG. 4 is a perspective view of bake station 12 shown FIG. 1 according to one embodiment of the invention; FIG. 5 is a perspective view of a cross-section of bake station 12 shown FIG. 4 and FIG. 6 is a cross-sectional view of the bake station. As shown in FIGS. 4-6, bake station 12 has three separate isothermal heating elements: bake plate 22, top heat plate 60 and side heat plate 62, each of which is manufactured from a material exhibiting high heat conductivity, such as aluminum or other appropriate material. Each plate 20, 60, 62 has a heating element, for example, resistive heating elements, embedded within the plate. Bake station 12 also includes side top and bottom heat shields 64 and 66, respectively, as well as a bottom cup 68 that surrounds bake plate 22 and a lid 70 (shown in FIG. 6 only). Each of heat shields 64, 66, cup 68 and lid 70 are made from aluminum. Lid 70 is attached to top heat plate 60 by eight screws that are threaded through threaded holes 72.

Bake plate 22 is operatively coupled to a motorized lift 28 so that the bake plate can be raised into a clam shell enclosure 24 and lowered into a wafer receiving position. Typically, wafers are heated on bake plate 22 when it is raised to a baking position within enclosure 24 indicated by dashed line 71 in FIG. 6. When in the baking position, cup 68 encircles a bottom portion of side heat plate 62 forming a clam shell arrangement that helps confine heat generated by bake plate 22 within an inner cavity formed by the bake plate and enclosure 24. In one embodiment the upper surface of bake plate 22 includes 8 wafer pocket buttons and 17 proximity pins similar to those described with respect to shuttle 18 and chill plate 30 below. As used herein, any discussion of placing a wafer on a surface of a bake plate, chill plate or shuttle encompasses either placing the wafer directly on the surface or placing the wafer onto support pins that maintain the wafer slightly above the surface. Also, in one embodiment bake plate 22 includes a plurality of vacuum ports operatively coupled to a vacuum chuck to secure a wafer to the bake plate during the baking process.

During the baking process, a faceplate 74 is positioned just above and opposite wafer support surface 20a of bake plate 20. Faceplate 74 can be made from aluminum as well as other suitable materials and includes a plurality of holes or channels 74a that allow gases and contaminants baked off the surface of a wafer being baked on bake plate 22 to drift through faceplate 74 and into a radially inward gas flow 76 that is created between faceplate 74 and top heat plate 60.

Gas from radially inward gas flow 76 is initially introduced into bake station 12 at an annular gas manifold 78 that encircles the outer portion of top heat plate 60 by a gas inlet line 80. Gas manifold 78 includes numerous small gas inlets 82 (128 inlets in one embodiment) that allow gas to flow from manifold 78 into the cavity 84 between the lower surface of top heat plate 60 and the upper surface of faceplate 74. The gas flows radially inward towards the center of the station through a diffusion plate 86 that includes a plurality of gas outlet holes 88. After flowing through diffusion plate 86, gas exits bake station 12 through gas outlet line 90.

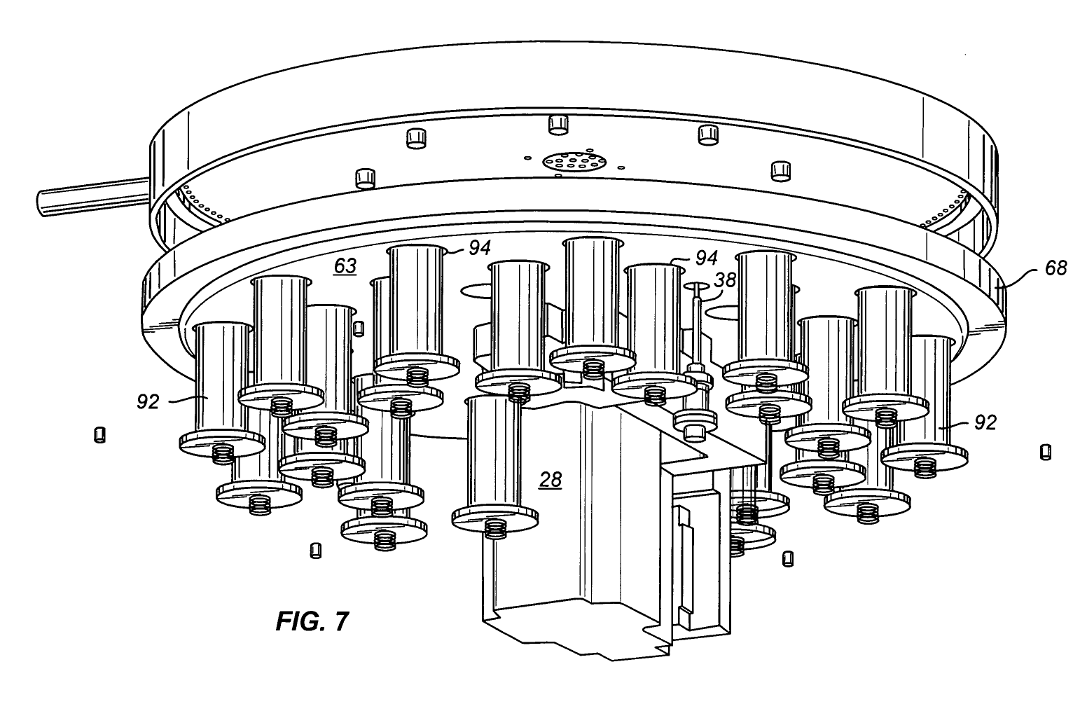

An aspect of some embodiments of the invention that helps minimize any delay associated with switching from one thermal recipe to another thermal recipe an thus helps ensure high wafer throughput through integrated thermal unit 10 is discussed below with respect to FIG. 7. FIG. 7 is a bottom perspective view of bake station 12 shown in FIGS. 4-6. As shown in FIG. 7, in one embodiment of the invention bake station 12 includes a plurality of engageable heat sinks 92. Each engageable heat sink 92 is made from an appropriate heat sink material, such as aluminum, copper, stainless steel or other metal.

As previously mentioned, bake plate 22 heats a wafer according to a particular thermal recipe. One component of the thermal recipe is typically a set point temperature at which the bake plate is set to heat the wafer. During the baking process, the temperature of the wafer is routinely measured and one or more zones of the bake plate can be adjusted to ensure uniform heating of the substrate. Typically bake plate is heated to the desired set point temperature while a large batch of wafers is processed according to the same thermal recipe. Thus, for example, if a particular thermal recipe calls for a set point temperature of 175° C. and that recipe is to be implemented on 100 consecutive wafers, bake plate 22 will be heated to 175° C. during the length of time it takes to process the 100 consecutive wafers. If, however, a subsequent batch of 200 wafers is to be processed according to a different thermal recipe that, for example, requires a set point temperature of 130° C., the set point temperature of bake plate 22 needs to be rapidly changed from 175° C. to 130° C. between processing the 100th and 101st wafers.

Some embodiments of the present invention enable a rapid reduction in the set point temperature of bake plate 22 by lowering the bake plate with motor 28 into a lower cooling position that is below the wafer receiving position. In the cooling position a bottom surface of the bake plate contacts an upper surface of each heat sink 92. Contact between the heat sinks and bake plate is possible because bottom cup 68 includes a plurality of holes 94 that correspond to the plurality of heat sinks 92 allowing the heat sinks to extend through bottom cup 68 to contact bake plate 20. Further details of engageable heat sinks 92 and their operation is set forth in U.S. application Ser. No. 11/174,988, entitled “An Integrated Thermal Unit Having a Shuttle With a Temperature Controlled Surface” filed on Jul. 5, 2005 which is incorporated by reference in its entirety.

Other embodiments of the invention enable a rapid reduction in the set point temperature of bake plate 22 when switching thermal recipes by moving shuttle 18 (typically without a wafer positioned on the shuttle) over the surface of bake plate 22 so that bake plate 22 and shuttle 18 are closely spaced (e.g., the upper surface of the bake plate and lower surface may be spaced less than 10 mm and preferably less than 5 mm from each other). As described below, shuttle 18 has channels formed therein in which cooling fluid circulates to maintain the shuttle at a constant relatively cool temperature. This temperature difference can be used to facilitate rapid cooling of the bake plate by introducing or flooding helium or another heat transfer gas can into the bake station.

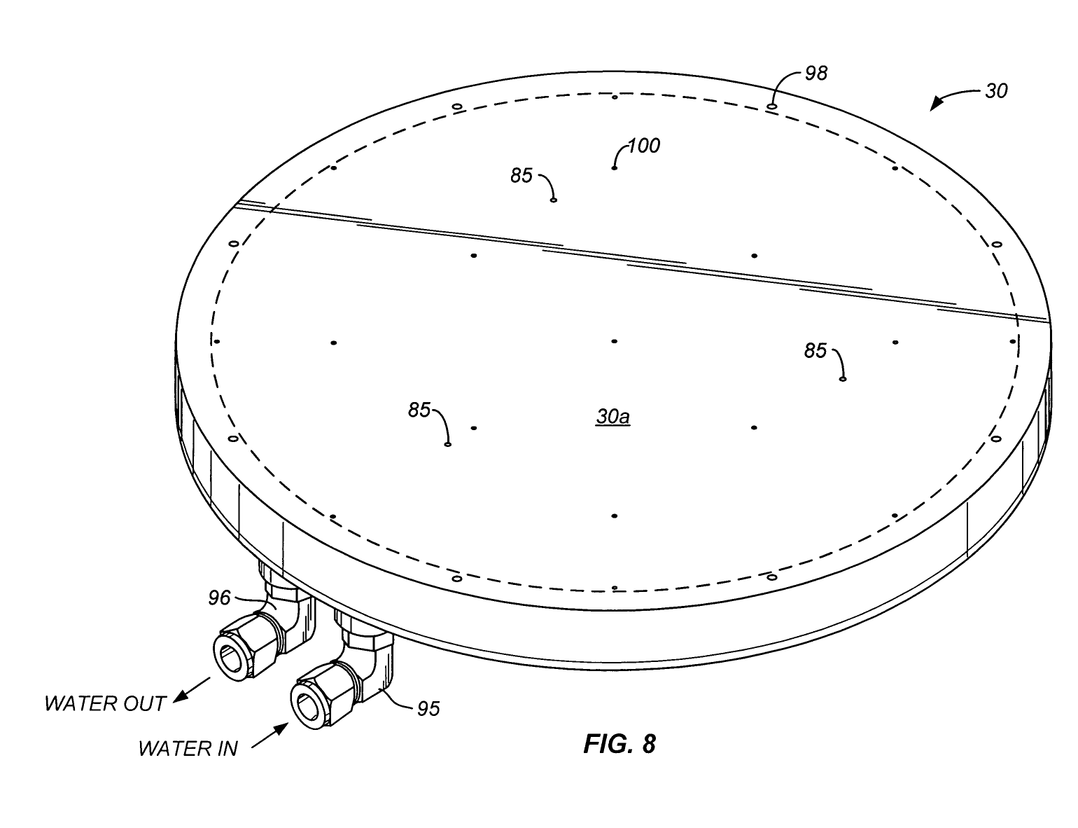

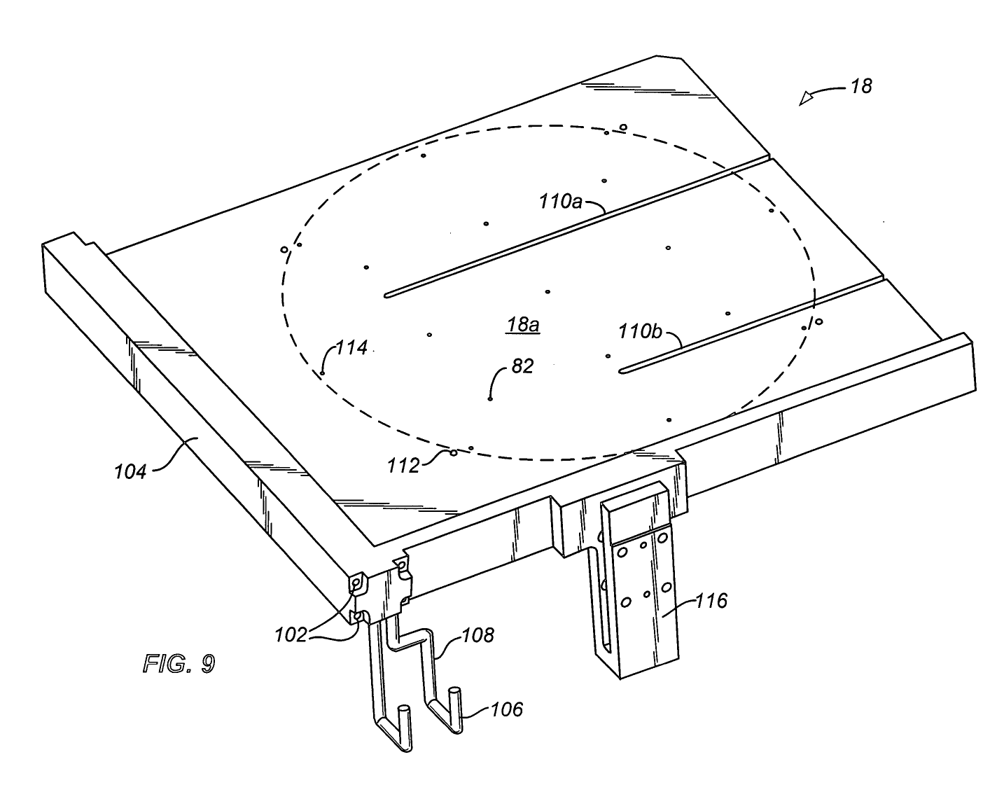

Referring now to FIG. 8, which is a perspective view of chill plate 30 according to one embodiment of the invention, chill plate 30 includes a coolant inlet 95 and outlet 96 that allow a coolant liquid, such as deionized water, to be circulated through coolant channels (not shown) to cool a wafer supported on wafer support surface 30a. Chill plate 30 also includes a number of wafer pocket buttons 98 and small contact area proximity pins 100 that are similar to buttons 42 and proximity pins 114 described below with respect to FIG. 9. In one particular embodiment, chill plate 30 includes eight pocket buttons 98 and seventeen proximity pins 100. Also, shown in FIG. 8 are three lift pin hole 85 that allow lift pins 32 to be raised by a drive mechanism, such as a pneumatic motor, to extend through surface 30a of the chill plate. The lift pins are used to lift a substrate off of shuttle 18 after the shuttle brings a substrate from bake station 12 to chill station 14 for cooling. After the substrate is raised above the surface of the shuttle, the shuttle is moved away from chill station 14 and the lift pins are lowered dropping the substrate onto surface 30a of the chill plate. Also, while not shown in FIG. 8, chill plate 30 may include a plurality of vacuum ports and be operatively coupled to a vacuum chuck to secure a wafer to the chill plate during the cooling process.

Another aspect of the present invention that helps ensure an extremely high degree of uniformity in the thermal treatment of each wafer is the design of shuttle 18. As shown in FIG. 9, which is a simplified perspective view of shuttle 18, the shuttle includes a wafer receiving area 18a upon which a semiconductor wafer is placed while the shuttle is transferring the wafer from one station to another. In one embodiment, shuttle 18 is made from aluminum and wafer receiving area 18a and other portions of an upper surface of the shuttle are actively cooled by a coolant (e.g., deionized water) that flows through coolant passages (not shown) in the shuttle.

The coolant is delivered to the coolant passages by tubes that connect to inlets/outlets 102, which in turn connect to a manifold (not shown) within portion 104 of shuttle 18 that helps distribute the fluid evenly throughout the shuttle. The fluid tubes are at least partially supported by fingers 106 of tube support mechanism 108 as shuttle 18 traverses the length of the integrated thermal unit. Actively cooling wafer receiving surface 18a helps maintain precise thermal control of wafer temperature during all times while the wafer is within thermal unit 10. Actively cooling shuttle 18 also starts the wafer cooling process sooner than it would otherwise be initiated if such active cooling did not occur until the wafer is transferred to a dedicated chill station, which in turn reduces the overall thermal budget of the wafer.

Also shown in FIG. 9 are slots 110a, 110b, wafer pocket buttons 112 and small contact area proximity pins 114. Slots 110a, 110b allow the shuttle to be positioned or moved under a wafer being held by lift pins. For example, in chill station 14 a wafer is held above the chill plate prior to and after a chill step on a set of three lift pins arranged in a triangular formation (see FIG. 8 showing holes 85 that allow the lift pins to extend through chill plate 30). Slot 110a is aligned to allow shuttle 18 to slide past two of the three lift pins and slot 110b is aligned to allow the shuttle to slide pass the third lift pin. Pocket buttons 112 screw into threaded holes in the upper surface of shuttle 18 and extend above the surface to help center a wafer within wafer receiving area 18a. Pocket buttons 112 can be made from any appropriately soft material, such as a thermoplastic material, that exhibits strong fatigue resistance and thermal stability. In one embodiment, buttons 112 are made from polyetheretherketone, which is also known as PEEK.

Proximity pins 114 are distributed across upper surface 18a of shuttle 18 and are fabricated from a material with a low coefficient of friction, such as sapphire. Proximity pins 114 allow the wafer being transported by shuttle 18 to be brought into very close proximity of temperature controlled surface 18a. The small space between the wafer and temperature controlled surface 18a helps create uniform cooling across the entire surface area of the wafer while at the same time minimizing contact between the underside of the wafer and the shuttle thus reducing the likelihood that particles or contaminants may be generated from such contact. Further details of proximity pins 114 are set forth in U.S. application Ser. No. 11/111,155, entitled “Purged Vacuum Chuck with Proximity Pins” filed on Apr. 20, 2005 (Attorney Docket No.: A9871/T60200), which is hereby incorporated by reference for all purposes. In one particular embodiment shuttle 18 includes four pocket buttons 112 and seventeen proximity pins 114. Shuttle 18 also includes a bracket 116 that allows the shuttle to be mounted to a motor that moves the shuttle within housing 20 linearly along the x-and z-axis as previously discussed.

In order to better appreciate and understand the general operation of integrated thermal unit 10, reference is now made to FIG. 10. FIG. 10 is a simplified block diagram that illustrates a sequence of events that is performed by thermal unit 10 to thermally treat wafers according to one embodiment of the method of the present invention. A wafer may be treated in accordance with the process set forth in FIG. 10 after, for example, having a photoresist layer deposited over the wafer at an appropriate coating station of a track lithography tool. While the discussion below focuses on treating a single wafer within unit 10, a person of skill in the art will appreciate that thermal unit 10 will often be used to simultaneously process two or three wafers. For example, while one wafer is being heated by bake station 12, thermal unit 10 can be in the process of cooling another wafer at chill station 14 and transferring still another wafer into the thermal unit at substrate receiving station 16.

As shown in FIG. 10, a wafer's history in thermal unit 10 starts by transferring the wafer into the thermal unit 10 through wafer transfer slot 40 and placing the wafer onto lift pins 38 (FIG. 1) at shuttle station 16 (FIG. 10, step 150). The wafer may be transferred into thermal unit 10 by, for example, a central robot that services both wafer transfer slots 40 and 42 as well as one or more coating or developing stations in a track lithography tool (not shown). Typically wafer transfer slot 40 is closed by shutter 44, thus step 50 also includes moving shutter 44 to open slot 40. After the wafer is properly positioned on lift pins 38, the robot arm recedes out of the thermal unit and shutter 44 is closed. Shuttle 18 can then be moved into a wafer receiving position at station 16 where lift pins 38 extend through slots 110a and 110b of the shuttle 18 and raised to lift the wafer off of stationary lift pins 38 (FIG. 10, step 151). Shuttle 18 can then be moved linearly out of portion 20b of thermal unit 10 into portion 20a. Once within portion 20a, the shuttle can be moved vertically to an appropriate height for transferring the wafer to bake station 12 and then linearly back into portion 20a to transfer the wafer to bake station 12 (FIG. 10, step 152).

At bake station 12, the wafer is placed on lift pins 38 and shuttle 18 is free to handle another task or return to a home position, for example at station 16 (FIG. 10, step 153). While the shuttle is being returned to home position, bake plate 22 is raised by motorized lift 28 thereby picking the wafer up off of stationary lift pins 34 and bringing the wafer into its bake position within clam shell enclosure 24 (FIG. 10, step 154). Once inside claim shell enclosure 24 the wafer is heated or baked according to a desired thermal recipe (FIG. 10, step 155).

After completion of bake step 55, the bake plate 20 is lowered to its wafer receiving position dropping the wafer off on lift pins 34 (FIG. 10, step 156). Next, shuttle 18 returns to bake station 12 and picks the wafer up off of lift pins 34 (FIG. 10, step 157) and brings the wafer to chill station 14 (FIG. 10, step 158). The path to chill station 14 includes moving the shuttle into portion 20a of thermal unit 10 where shuttle 18 is lowered to the height of chill station 14 and then moved towards the chill station. Once at chill station 14, lift pins 32 are raised by a pneumatic lift to lift the wafer off of the shuttle (FIG. 10, step 159). Shuttle 18 is then free to handle another task or return to its home position at station 16 (FIG. 10, step 160) and lift pins 32 are lowered to drop the wafer of onto surface 30a of chill plate 30 (FIG. 10, step 161).

The wafer is then cooled on chill plate 30 according to a predetermined thermal recipe (FIG. 10, step 162). After completion of the cooling process, lift pins 32 are raised to pick the wafer up off of the chill plate (FIG. 10, step 163) and the wafer is transferred out of the integrated thermal unit through elongated slot 42 (FIG. 10, step 164) by, for example, being picked up by the same central robot that transferred the wafer into the thermal unit in step 150. Typically, elongated slot 42 is closed by shutter 46, thus step 64 also includes opening shutter 46 to open slot 42 and closing shutter 46 after the wafer is transferred out of the thermal unit.

Embodiments of the invention allow a process such as that described above to be carried out in a highly controllable and highly repeatable manner. Thus, embodiments of the invention help ensure an extremely high degree of uniformity in the thermal treatment of each wafer that is processed within integrated thermal unit 10 according to a particular thermal recipe.

FIG. 11 is a plan view of an embodiment of a track lithography tool 200 in which the embodiments of the present invention may be used. As illustrated in FIG. 1, track lithography tool 200 contains a front end module 210 (sometimes referred to as a factory interface or FI) and a process module 211. In other embodiments, the track lithography tool 200 includes a rear module (not shown), which is sometimes referred to as a scanner interface. Front end module 210 generally contains one or more pod assemblies or FOUPS (e.g., items 205A-D) and a front end robot assembly 215 including a horizontal motion assembly 216 and a front end robot 217. The front end module 210 may also include front end processing racks (not shown). The one or more pod assemblies 205A-D are generally adapted to accept one or more cassettes 206 that may contain one or more substrates or wafers, “W,” that are to be processed in track lithography tool 200. The front end module 210 may also contain one or more pass-through positions (not shown) to link the front end module 210 and the process module 211.

Process module 211 generally contains a number of processing racks 220A, 220B, 230, and 236. As illustrated in FIG. 1, processing racks 220A and 220B each include a coater/developer module with shared dispense 224. A coater/developer module with shared dispense 224 includes two coat bowls 221 positioned on opposing sides of a shared dispense bank 222, which contains a number of nozzles 223 providing processing fluids (e.g., bottom anti-reflection coating (BARC) liquid, resist, developer, and the like) to a wafer mounted on a substrate support 227 located in the coat bowl 221. In the embodiment illustrated in FIG. 1, a dispense arm 225 sliding along a track 226 is able to pick up a nozzle 223 from the shared dispense bank 222 and position the selected nozzle over the wafer for dispense operations. Of course, coat bowls with dedicated dispense banks are provided in alternative embodiments.

Processing rack 230 includes an integrated thermal unit 134, such as integrated thermal unit 10 according to the present invention. The integrated thermal unit is utilized in heat treatment operations including post exposure bake (PEB), post-resist bake, and the like. Processing rack 236 includes an integrated bake and chill unit 239, with two bake plates 237A and 237B served by a single chill plate 238.

One or more robot assemblies (robots) 240 are adapted to access the front-end module 210, the various processing modules or chambers retained in the processing racks 220A, 220B, 230, and 236, and the scanner 250. By transferring substrates between these various components, a desired processing sequence can be performed on the substrates. The two robots 240 illustrated in FIG. 1 are configured in a parallel processing configuration and travel in the x-direction along horizontal motion assembly 242. Utilizing a mast structure (not shown), the robots 240 are also adapted to move in a vertical (z-direction) and horizontal directions, i.e., transfer direction (x-direction) and a direction orthogonal to the transfer direction (y-direction). Utilizing one or more of these three directional motion capabilities, robots 240 are able to place wafers in and transfer wafers between the various processing chambers retained in the processing racks that are aligned along the transfer direction.

The first robot assembly 240A and the second robot assembly 240B are adapted to transfer substrates to the various processing chambers contained in the processing racks 220A, 220B, 230, and 236. In one embodiment, to perform the process of transferring substrates in the track lithography tool 200, robot assembly 240A and robot assembly 240B are similarly configured and include at least one horizontal motion assembly 242, a vertical motion assembly 244, and a robot hardware assembly 243 supporting a robot blade 245. robot assemblies 240 are in communication with a system controller 260. In the embodiment illustrated in FIG. 11, a rear robot assembly 248 is also provided.

The scanner 250, which may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner 250 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 220A, 220B, 230, and 236 contain multiple processing modules in a vertically stacked arrangement. That is, each of the processing racks may contain multiple stacked coater/developer modules with shared dispense 224, multiple stacked integrated thermal units 234, multiple stacked integrated bake and chill units 239, or other modules that are adapted to perform the various processing steps required of a track photolithography tool. As examples, coater/developer modules with shared dispense 224 may be used to deposit a bottom antireflective coating (BARC) and/or deposit and/or develop photoresist layers. Integrated thermal units 234 and integrated bake and chill units 239 may perform bake and chill operations associated with hardening BARC and/or photoresist layers after application or exposure.

In one embodiment, a system controller 260 is used to control all of the components and processes performed in the cluster tool 200. The controller 260 is generally adapted to communicate with the scanner 250, monitor and control aspects of the processes performed in the cluster tool 200, and is adapted to control all aspects of the complete substrate processing sequence. The controller 160-260, which is typically a microprocessor-based controller, is configured to receive inputs from a user and/or various sensors in one of the processing chambers and appropriately control the processing chamber components in accordance with the various inputs and software instructions retained in the controller's memory. The controller 240 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 260 determines which tasks are performable in the processing chamber(s). Preferably, the program is software readable by the controller 260 and includes instructions to monitor and control the process based on defined rules and input data.

It is to be understood that embodiments of the invention are not limited to use with a track lithography tool such as that depicted in FIG. 11. Instead, embodiments of the invention may be used in any track lithography tool including the many different tool configurations described in U.S. application Ser. No. 11/315,984, entitled “Cartesian Robot Cluster Tool Architecture” filed on Dec. 22, 2005, which is hereby incorporated by reference for all purposes and including configurations not described in the above referenced application.

FIG. 12 is a flowchart illustrating an exemplary processing sequence for a semiconductor substrate processed within track lithography tool 200. A person of skill in the art will appreciate that the various process steps discussed below with respect to FIG. 12 present a number of different opportunities for the methods of the present inventions to be employed. The skilled artisan will also appreciate that various embodiments of the methods of the invention are not limited to the particular processing sequence set forth in FIG. 12 and can instead be used in any sequence of process steps or any application where it is desirable to exhibit a high degree of control over the thermal processing (and in particular complimentary bake and chill steps) of a plurality of substrates according to a particular process recipe.

FIG. 12 illustrates one embodiment of a series of method steps 300 that may be used to deposit, expose and develop a photoresist material layer formed on a substrate surface. The lithographic process may generally contain the following: a transfer substrate to coat module step 310, a bottom anti-reflective coating (BARC) coat step 312, a post BARC bake step 314, a post BARC chill step 316, a photoresist coat step 318, a post photoresist bake step 320, a post photoresist chill step 322, an optical edge bead removal (OEBR) step 324, an exposure step 326, a post exposure bake (PEB) step 328, a post exposure bake chill step 330, a develop step 332, a substrate rinse step 334, a post develop chill step 336 and a transfer substrate to pod step 338. In other embodiments, the sequence of the method steps 300 may be rearranged, altered, one or more steps may be removed, additional steps added or two or more steps may be combined into a single step with out varying from the basic scope of the invention.

In step 310, a semiconductor substrate is transferred to a coat module. Referring to FIG. 11, the step of transferring the substrate to the coat module 310 is generally defined as the process of having front end robot 217 remove a substrate from a cassette 206 resting in one of the pod assemblies 205A-D. A cassette 206, containing one or more substrates “W”, is placed on the pod assembly 205A-D by the user or some external device (not shown) so that the substrates can be processed in the cluster tool 200 by a user-defined substrate processing sequence controlled by software retained in the system controller 260.

The BARC coat step 310 is a step used to deposit an organic material over a surface of the substrate. The BARC layer is typically an organic coating that is applied onto the substrate prior to the photoresist layer to absorb light that otherwise would be reflected from the surface of the substrate back into the resist during the exposure step 326 performed in the stepper/scanner 150. If these reflections are not prevented, standing waves will be established in the resist layer, which cause feature size to vary from one location to another depending on the local thickness of the resist layer. The BARC layer may also be used to level (or planarize) the substrate surface topography, which is generally present after completing multiple electronic device fabrication steps. The BARC material fills around and over the features to create a flatter surface for photoresist application and reduces local variations in resist thickness.

BARC coat step 310 is typically performed using a conventional spin-on resist dispense process in which an amount of the BARC material is deposited on the surface of the substrate while the substrate is being rotated which causes a solvent in the BARC material to evaporate and thus causes the material properties of the deposited BARC material to change. The air flow and exhaust flow rate in the BARC processing chamber is often controlled to control the solvent vaporization process and the properties of the layer formed on the substrate surface.

Post BARC bake step 314, is a step used to assure that all of the solvent is removed from the deposited BARC layer in BARC coat step 312, and in some cases to promote adhesion of the BARC layer to the surface of the substrate. The temperature of post BARC bake step 314 is dependent on the type of BARC material deposited on the surface of the substrate, but will generally be less than about 250° C. The time required to complete post BARC bake step 314 will depend on the temperature of the substrate during the post BARC bake step, but will generally be less than about 60 seconds.

Post BARC chill step 316, is a step used to control and assure that the time the substrate is above ambient temperature is consistent so that every substrate sees the same time-temperature profile and thus process variability is minimized. Variations in the BARC process time-temperature profile, which is a component of a substrates wafer history, can have an effect on the properties of the deposited film layer and thus is often controlled to minimize process variability. Post BARC chill step 316, is typically used to cool the substrate after post BARC bake step 314 to a temperature at or near ambient temperature. The time required to complete post BARC chill step 316 will depend on the temperature of the substrate exiting the post BARC bake step, but will generally be less than about 30 seconds.

Photoresist coat step 318, is a step used to deposit a photoresist layer over a surface of the substrate. The photoresist layer deposited during the photoresist coat step 318 is typically a light sensitive organic coating that is applied onto the substrate and is later exposed in the stepper/scanner 5 to form the patterned features on the surface of the substrate. Photoresist coat step 318 is a typically performed using conventional spin-on resist dispense process in which an amount of the photoresist material is deposited on the surface of the substrate while the substrate is being rotated which causes a solvent in the photoresist material to evaporate and thus causes the material properties of the deposited photoresist layer to change. The air flow and exhaust flow rate in the photoresist processing chamber is controlled to control the solvent vaporization process and the properties of the layer formed on the substrate surface. In some cases it may be necessary to control the partial pressure of the solvent over the substrate surface to control the vaporization of the solvent from the resist during the photoresist coat step by controlling the exhaust flow rate and/or by injecting a solvent near the substrate surface. Referring to FIG. 11, in an exemplary photoresist coating process, the substrate is first positioned on a wafer chuck in coater/developer module 224. A motor rotates the wafer chuck and substrate while the photoresist is dispensed onto the center of the substrate. The rotation imparts an angular torque onto the photoresist, which forces the photoresist out in a radial direction, to ultimately covering the substrate.

Photoresist bake step 320, is a step used to assure that all of the solvent is removed from the deposited photoresist layer in photoresist coat step 318, and in some cases to promote adhesion of the photoresist layer to the BARC layer. The temperature of post photoresist bake step 320 is dependent on the type of photoresist material deposited on the surface of the substrate, but will generally be less than about 350° C. The time required to complete post photoresist bake step 320 will depend on the temperature of the substrate during the post photoresist bake step, but will generally be less than about 60 seconds.

Post photoresist chill step 322, is a step used to control the time the substrate is at a temperature above ambient temperature so that every substrate sees the same time-temperature profile and thus process variability is minimized. Variations in the time-temperature profile can have an effect on properties of the deposited film layer and thus is often controlled to minimize process variability. The temperature of post photoresist chill step 322, is thus used to cool the substrate after post photoresist bake step 320 to a temperature at or near ambient temperature. The time required to complete post photoresist chill step 322 will depend on the temperature of the substrate exiting the post photoresist bake step, but will generally be less than about 30 seconds.

Optical edge bead removal (OEBR) step 324, is a process used to expose the deposited light sensitive photoresist layer(s), such as, the layers formed during photoresist coat step 318 and the BARC layer formed during BARC coat step 312, to a radiation source (not shown) so that either or both layers can be removed from the edge of the substrate and the edge exclusion of the deposited layers can be more uniformly controlled. The wavelength and intensity of the radiation used to expose the surface of the substrate will depend on the type of BARC and photoresist layers deposited on the surface of the substrate. An OEBR tool can be purchased, for example, from USHIO America, Inc. Cypress, Calif.

Exposure step 326, is a lithographic projection step applied by a lithographic projection apparatus (e.g., stepper scanner 250) to form a pattern which is used to manufacture integrated circuits (ICs). The exposure step 326 forms a circuit pattern corresponding to an individual layer of the integrated circuit (IC) device on the substrate surface, by exposing the photosensitive materials, such as, the photoresist layer formed during photoresist coat step 318 and the BARC layer formed during the BARC coat step 312 of some form of electromagnetic radiation.

Post exposure bake (PEB) step 328, is a step used to heat a substrate immediately after exposure step 326 in order to stimulate diffusion of the photoactive compound(s) and reduce the effects of standing waves in the resist layer. For a chemically amplified resist, the PEB step also causes a catalyzed chemical reaction that changes the solubility of the resist. The control of the temperature during the PEB is typically critical to critical dimension (CD) control. The temperature of PEB step 328 is dependent on the type of photoresist material deposited on the surface of the substrate, but will generally be less than about 250° C. The time required to complete PEB step 328 will depend on the temperature of the substrate during the PEB step, but will generally be less than about 60 seconds.

Post exposure bake (PEB) chill step 330, is a step used to control the assure that the time the substrate is at a temperature above ambient temperature is controlled so that every substrate sees the same time-temperature profile and thus process variability is minimized. Variations in the PEB process time-temperature profile can have an effect on properties of the deposited film layer and thus is often controlled to minimize process variability. The temperature of PEB chill step 330, is thus used to cool the substrate after PEB step 328 to a temperature at or near ambient temperature. The time required to complete PEB chill step 330 will depend on the temperature of the substrate exiting the PEB step, but will generally be less than about 30 seconds.

Develop step 332, is a process in which a solvent is used to cause a chemical or physical change to the exposed or unexposed photoresist and BARC layers to expose the pattern formed during exposure process step 326. The develop process may be a spray or immersion or puddle type process that is used to dispense the developer solvent. In some develop processes, the substrate is coated with a fluid layer, typically deionized water, prior to application of the developer solution and spun during the development process. Subsequent application of the developer solution results in uniform coating of the developer on the substrate surface. In step 334, a rinse solution is provided to surface of the substrate, terminating the develop process. Merely by way of example, the rinse solution may be deionized water. In alternative embodiments, a rinse solution of deionized water combined with a surfactant is provided. One of ordinary skill in the art would recognize many variations, modifications, and alternatives.

In step 336, the substrate is cooled after the develop and rinse stets 332 and 334. In step 338, the substrate is transferred to the pod, thus completing the processing sequence. Transferring the substrate to the pod in step 338 generally entails the process of having the front end robot 218 return the substrate to a cassette 230 resting in one of the pod assemblies 216.

Based on the description of the present invention herein, a person of skill in the art will appreciate that embodiments of the invention may be beneficially used to heat and/or cool a substrate during, among other steps not described in FIG. 13, post BARC bake step 314 and post BARC chill step 316, during post PR bake step 320 and post PR chill step 322, during post exposure bake step 328 and post exposure chill step 330 and during post develop chill step 336. A skilled artisan will also appreciate some of the various bake and chill sequences set just described have differing bake and or chill requirements. Thus, the skilled artisan will appreciate that the functional specifications of a particular bake plate 22 and/or chill plate 30 incorporated into the integrated thermal unit will depend on the material the bake and/or chill plate are intended to heat and cool, respectively. For example, BARC materials may be adequately heated with a low temperature, low precision bake plate (e.g., a maximum 250° C., single zone heater) while photoresist materials may require a high temperature, mid-precision bake plate (e.g., a maximum 350° C., three zone heater) and the post exposure bake process may require a low temperature, high precision bake plate (e.g., a maximum 250° C., fifteen zone heater). Thus, embodiments of the invention are not limited to any particular type of or configuration of bake plate 22 or chill plate 30. Instead, generally each of bake plate 22 and chill plate 30 is designed to particular performance standards as required by the application for which the bake plate and chill plate will be used as can be determined by a person of skill in the art.

While the present invention has been described with respect to particular embodiments and specific examples thereof, it should be understood that other embodiments may fall within the spirit and scope of the invention. For example, while FIGS. 1-3 show bake station 12 positioned vertically above chill station 14, other embodiments of the invention position chill station 14 vertically above back station 12. The scope of the invention should, therefore, be determined with reference to the appended claims along with their full scope of equivalents.

What is claimed is:

1. An integrated thermal unit comprising:
a housing;
a bake station positioned within the housing, the bake station comprising a bake plate configured to heat a substrate supported on a surface of the bake plate;
a chill station positioned within the housing, the chill station comprising a chill plate configured to cool a substrate supported on a surface of the chill plate; and
a substrate receiving station positioned within the housing, the substrate receiving station configured to hold a substrate;
wherein the bake station, chill station and substrate receiving station are arranged in a vertical stack within the housing.

2. The integrated thermal unit of claim 1 further comprising a substrate transfer shuttle positioned within the housing, the shuttle adapted to transfer substrates between the substrate receiving station, bake station and chill stations.

3. The integrated thermal unit of claim 2 wherein the substrate transfer shuttle is adapted to move linearly along an x-and z-axis within the housing with movement along the z-axis occurring in a portion of the housing laterally adjacent to the portion of the housing in which the bake station, chill station and substrate receiving station are vertically stacked.

4. The integrated thermal unit of claim 2 wherein the substrate transfer shuttle is configured to actively cool a substrate while transferring the substrate from the bake station to the chill station.

5. The integrated thermal unit of claim 4 wherein the substrate transfer shuttle comprises a plurality of coolant channels underneath a substrate receiving surface.

6. The integrated thermal unit of claim 4 wherein the substrate transfer shuttle comprises first and second elongated slots, wherein the elongated slots traverse a thickness of the shuttle's substrate receiving surface and are open at one end of the substrate receiving surface but do not traverse the entire length of the substrate receiving surface.

7. The integrated thermal unit of claim 2 wherein the bake station is positioned over the chill station.

8. The integrated thermal unit of claim 2 wherein the chill station is positioned over the bake station.

9. The integrated thermal unit of claim 2 wherein the housing comprises a first access slot and a second access slot, each of the first and second access slots sized to allow a semiconductor substrate to be transferred into or out of the housing.

10. The integrated thermal unit of claim 9 wherein the first access slot is positioned horizontally adjacent to the substrate receiving station such that a substrate can be transferred into the integrated thermal unit through the first access slot and placed on the substrate receiving station and wherein the second access slot is positioned horizontally adjacent to the chill station such that a substrate can be transferred out of the integrated thermal unit from the chill station through the second access slot.

11. The integrated thermal unit of claim 10 further comprising:
a first access shutter operatively configured to move between an open position that allows a substrate to be transferred through the first access slot and a closed position that blocks a substrate from being transferred through the first access slot; and
a second access shutter operatively configured to move between an open position that allows a substrate to be transferred through the second access slot and a closed position that blocks a substrate from being transferred through the second access slot.

12. A method of processing a substrate in an integrated thermal unit having a bake station, a chill station and a substrate receiving station arranged in a vertical stack within a housing, the method comprising:
transferring a substrate having a liquid resist material applied thereon into the integrated thermal unit and onto the substrate receiving station;
transferring the substrate from the substrate receiving station to the bake station with the substrate transfer device contained within the integrated thermal unit housing;
heating the substrate on a bake plate within the bake station;
transferring the substrate from the bake station to the chill station with the substrate transfer device;
cooling the substrate on a chill plate within the chill station; and
transferring the substrate from the chill station out of the integrated thermal unit.

13. The method of processing a substrate as set forth in claim 12 wherein the substrate transfer device comprises a substrate shuttle that is adapted to move linearly along the x-and z-axis.

14. The method of processing a substrate as set forth in claim 13 wherein movement of the substrate transfer shuttle along the z-axis occurs in a portion of the housing laterally adjacent to the portion of the housing in which the bake station, chill station and substrate receiving station are vertically stacked.

15. The method of processing a substrate as set forth in claim 14 wherein the step that transfers the substrate from the bake station to the chill station moves the substrate up along the z-axis.

16. The method of processing a substrate as set forth in claim 14 wherein the step that transfers the substrate from the bake station to the chill station moves the substrate down along the z-axis.

17. The method of processing a substrate as set forth in claim 13 wherein the step of transferring a substrate into the integrated thermal unit comprises placing the substrate on a plurality of lift pins arranged at the substrate receiving station.

18. The method of processing a substrate as set forth in claim 17 wherein the step of transferring the substrate from the bake station to the chill station comprises cooling the substrate with a temperature controlled surface.

19. A track lithography tool comprising:
a plurality of pod assemblies adapted to accept one or more cassettes of wafers;
one or more robots adapted to transfer wafers from the one or more pod assemblies to processing modules within the track lithography tool, wherein at least one of the processing modules includes an integrated thermal unit comprising:
a housing;
a bake station positioned within the housing, the bake station comprising a bake plate configured to heat a substrate supported on a surface of the bake plate;
a chill station positioned within the housing, the chill station comprising a chill plate configured to cool a substrate supported on a surface of the chill plate; and
a substrate receiving station positioned within the housing, the substrate receiving station configured to hold a substrate; and
a substrate transfer shuttle positioned within the housing, the shuttle adapted to transfer substrates between the substrate receiving station, bake station and chill stations;
wherein the bake station, chill station and substrate receiving station are arranged in a vertical stack within the housing.

20. The track lithography tool of claim 19 further comprising a plurality of the integrated thermal units arranged in a vertical stack.
